(19) United States
(12) Patent Application Publication
(10) Pub. No.: US 2008/0153200 A1
(43) Pub. Date: Jun. 26, 2008

(54) Stacked semiconductor components

(76) Inventor: Arkalgud Sitaram, Cedar Park, TX (US)

Correspondence Address: SLATER & MATSIL LLP, 17950 PRESTON ROAD, SUITE 1000, DALLAS, TX, 75252, US

(21) Appl. No.: 11/644,329

(22) Filed: Dec. 22, 2006

(51) Int. Cl. H01L 21/00

(52) U.S. Cl. 438/106

(57) ABSTRACT

A first semiconductor chip is formed using a first process technology. A plurality of through-vias are formed in the first semiconductor chip and the first semiconductor chip is thinned such that each through-via extends from the upper surface to the lower surface of the chip. A second semiconductor chip is formed using a second process technology that is different than the first process technology. The second semiconductor chip has a plurality of contacts at a surface. The first semiconductor chip is mounted adjacent the semiconductor chip such that ones of the through-vias are electrically coupled to associated ones of the contacts.

### TECHNICAL FIELD

This invention relates generally to electronic devices, and more particularly to stacked semiconductor components.

### BACKGROUND

One of the goals in the fabrication of electronic components is to minimize the size of various components. For example, it is desirable that hand held devices such as cellular telephones and personal digital assistants (PDAs) be as small as possible. To achieve this goal, the semiconductor circuits that are included within the devices should be as small as possible. One way of making these circuits smaller is to stack the chips that carry the circuits.

A number of ways of interconnecting the chips within the stack are known. For example, bond pads formed at the surface of each chip can be wire-bonded, either to a common substrate or to other chips in the stack. Another example is a so-called micro-bump 3D package, where each chip includes a number of micro-bumps that are routed to a circuit board, e.g., along an outer edge of the chip.

Yet another way of interconnecting chips within the stack is to use through-vias. Through-vias extend through the substrate thereby electrically interconnecting circuits on various chips. Through-via interconnections can provide advantages in terms of interconnect density compared to other technologies. While there is, in theory, no limit as to the number of chips that can be stacked, the ability to remove heat from inside the stack can limit the number of chips as a practical matter.

### SUMMARY OF THE INVENTION

A first semiconductor chip is formed using a first process technology. A plurality of through-vias are formed in the first semiconductor chip and the first semiconductor chip is thinned such that each through-via extends from the upper surface to the lower surface of the chip. A second semiconductor chip is formed using a second process technology that is different than the first process technology. The second semiconductor chip has a plurality of contacts at a surface. The first semiconductor chip is mounted adjacent the semiconductor chip, such that ones of the through-vias are electrically coupled to associated ones of the contacts.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a view of a first embodiment stacked arrangement;

FIG. 2 is a flow chart of one embodiment to form the stacked arrangement;

FIG. 3 is a view of a non-volatile memory embodiment;

FIG. 4 is schematic/block diagram of the embodiment of FIG. 3;

FIG. 5 is an alternate embodiment of a non-volatile memory device;

FIG. 6 is a view of a memory embodiment of the present invention;

FIG. 7 is a block diagram of a memory embodiment; and

FIG. 8 is a schematic diagram of a DRAM embodiment.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a non-volatile memory device. The invention may also be applied, however, to other semiconductor components, a few examples of which will be explicitly described below. One of ordinary skill in the art will be able to recognize further examples as well.

Embodiments of the present invention utilized stacking to create 3D chip packages. Stacking chips on top of one another provides a means to achieve density, increased functionality and/or additional performance. One way to realize the full benefits of chip stacking is to connect the chips using deep, or through-vias. These vias extend from the active circuitry at one face of the chip to a bottom surface of the chip.

One of the issues with conventional flash scaling is the scaling of high voltage (HV) circuitry. The voltages used in these circuits can range up to 15 to 20V, depending on the technology, and it becomes extremely difficult for the high voltage portions of the chip to keep pace with the scaling of the flash memory array. In one aspect, the present invention utilizes 3D chip stacking to circumvent this problem.

In one embodiment, the high voltage and low voltage circuitries are separated to different levels of the 3D stack. As a result of this separation, the issue of process compatibility is resolved and the result is a low cost flash chip stack where both the low and the high voltage elements are optimized to provide the best performance and the lowest cost. As will be described herein, this concept can also be applied to other applications.

In one example, the low voltage sections of the flash chip (including the array areas) are laid out so that through-vias, e.g., through silicon contacts, from the high voltage sections of the flash chip can connect to the appropriate points. The low and high voltage areas of the chips are processed as separate levels and then bonded together to form a low cost 3D flash stack. Additional levels can be added as per layout guidelines and density requirements of the product.

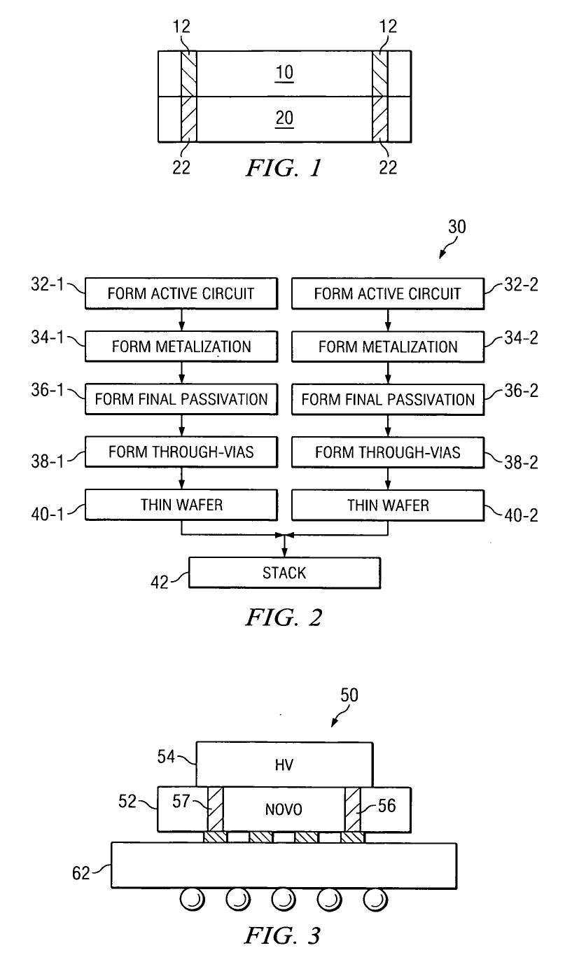

A simplified example is shown in FIG. 1. In this figure, a first chip 10 is mounted over a second chip 20. The chips 10 and 20 are typically single substrate semiconductor dies that are electrically coupled, at least in part, by through-vias 12 and 22. For the purpose of illustration, only two through-vias are shown. In practical applications, a larger number of vias can be used. The chips 10 and 20 can also be electrically coupled using other connections, e.g., contact bumps or wire bonds.

The active circuitry, e.g., transistors and other components, can be formed at either surface of the chips. For example, the chips can be mounted face-to-face (i.e., active circuitry of one chip being adjacent to active circuitry of the other), back-to-back or face-to-back. Two chips are shown but it is understood that stacks with more chips can be manufactured. Further, both chips are illustrated to have through-vias. In other embodiments, only one (or neither) of the chips would include a through-via.

The fabrication of a component as illustrated in FIG. 1 will now be described with respect to the flow chart 30 of FIG. 2. The left side of flow chart 30 is provided to describe the process to manufacture the first chip 10, while the right side of the flow chart 30 is provided to describe the process to manufacture the second chip 20. Accordingly, the reference numbers include a “−1” or “−2.” Generic description to either step will leave out the hyphenated portion.

As illustrated by box 32, active circuitry is formed at a surface of a semiconductor wafer. This integrated circuitry can include transistors, resistors, capacitors, inductors or other components used to form integrated circuits. For example, active areas that include transistors (e.g., CMOS transistors) can be separated from one another by isolation regions, e.g., shallow trench isolation. This processing can be referred to as front-end or front end of line (FEOL) processing.

In the preferred embodiment, the first chip 10 is formed using a first process technology and the second chip 20 is formed using a second process technology that is different than the first process technology. One of the challenges of fabricating advanced semiconductor products is the compatibility of various process technologies. For example, in the case of flash memory as discussed above, the high voltage regions have large dimensions, while the cell array can be scaled to smaller dimensions. Integrating the different process technologies can increase process costs, degrade yield and impact performance. While layout dimensions can be accounted for by simply devoting the appropriate real estate to each portion, processes must be adjusted to produce other device features. Continuing with the flash example, thick gate dielectrics are used in the high voltage circuitry and thin gate dielectrics are used in the memory array. Other differences can include junction depths, implant concentrations, and others.

To this point, the only example provided has been the high voltage/low voltage scenario, such as would be present in a flash (or other non-volatile) memory. As stated above, the concepts also apply to other process technologies. For example, the first semiconductor chip 10 can be formed to include analog circuits while the second semiconductor chip 20 can be formed to include digital circuits. Such mixed signal products are often fabricated using different process technologies.

As just one specific example, concepts of the present invention can be utilized in a device that includes an analog-to-digital circuit. A device of this type might include an array of capacitors that are precisely fabricated to varying (or identical) values. In one embodiment, these capacitors could be fabricated using high dielectric materials that may be incompatible, or at least inconvenient to be used, with the materials of the remainder of the circuitry. In this case, the first chip 10 can include the capacitor array while the second chip 20 includes other circuitry.

In another embodiment, the first semiconductor chip 10 uses a process technology that forms bipolar devices while the second semiconductor chip 20 uses a second process technology that forms CMOS devices. Conventional BiCMOS devices are formed on a single chip by carefully integrating the two processes. Using concepts of the present invention, two separate wafers can be fabricated, each being optimized to the specific technologies. Components that must be closely linked can be interconnected using the through-vias 12 and/or 22 so that performance will not be sacrificed.

In yet another embodiment, the first semiconductor chip 10 uses a second process technology that forms an array of memory cells and the second semiconductor chip 20 uses a second process technology that forms peripheral circuitry coupled to the array of memory cells through the through-vias 12 and/or 22. For example, the peripheral circuitry can be operable to access information to and from addressed areas of the array. As will be discussed in further detail below, the array of memory cells can be an array of dynamic random access memory cells.

The preceding paragraphs provide a few specific examples of technologies that can utilize aspects of the present invention. Other technologies could also be utilized.

Returning to FIG. 2, the box 34 is provided to show that the components formed during the front-end processing can then be interconnected by metallization, sometimes referred to as back end of line (BEOL) processing. Metallization is formed over the active circuitry and in electrical contact with the active circuitry. The metallization and active circuitry together form a completed functional integrated circuit. In other words, the electrical functions of the chip can be performed by the interconnected active circuitry. In a logic chip, the metallization may include many layers, e.g., nine or more, of copper. In other devices, such as DRAMs, the metallization may be aluminum. In other examples, other materials can be used. In fact, the metallization need not actually be metal if other conductors are used.

Referring now to box 36, a final passivation layer is formed over the metallization layer. The final passivation layer can include more than one layer of material, such as silicon oxide, silicon nitride or silicon oxynitride or polyimide, as just a few examples. The final passivation layer includes openings to expose the contact areas.

The formation of the through-vias is illustrated by box 38. A plurality of through-vias can be formed through the semiconductor wafer, i.e., extending from the front-side surface to the back-side surface. The through-vias are electrically coupled as described herein. The flow chart of FIG. 2 includes both a box 38-1 and a box 38-2. It is understood, however, that the through-via may extend through only one of the chips. For example, the top chip in the stack may not include through-vias. As another example, the bottom chip in the stack may be coupled to a board by alternate means.

Optionally, the wafer may be thinned from the back-side, e.g., through grinding, as indicated by box 40. The advantage of thinning the wafer (or chip, if the wafer has already been singulated) is to create a lower profile component, and to shorten the length of the through-vias, which enhances the electric properties and speeds up the via etch processing.

Box 42 is provided to indicate that the completed components can then be stacked together. One method of stacking two components is provided in co-pending application Ser. No. 11/602,536, which was filed on Nov. 21, 2006 and is incorporated herein by reference.

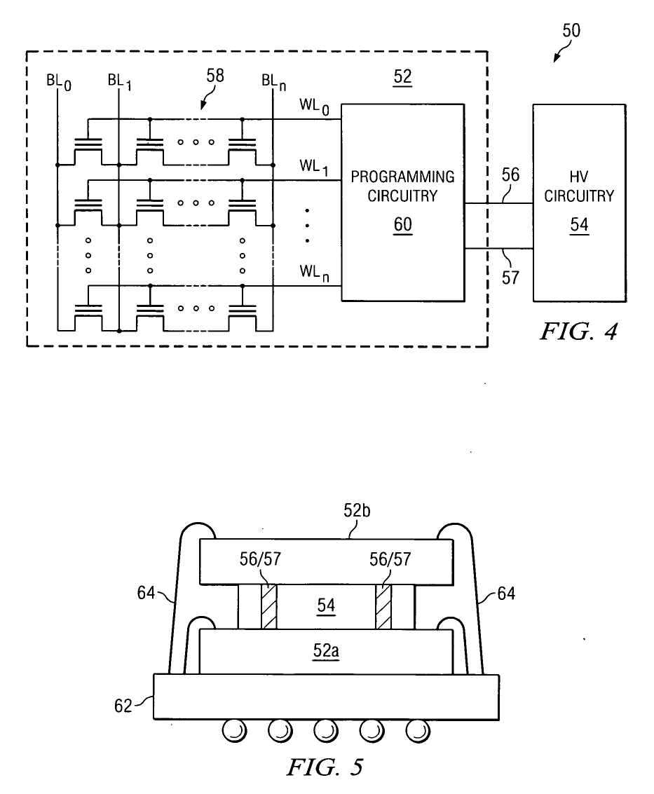

As discussed above, in one embodiment, a non-volatile memory array is stacked with higher voltage circuitry that can be utilized to program the array. Such an example is described in further detail with respect to FIGS. 3 and 4.

Referring now to FIG. 3, a memory device 50 includes a first semiconductor chip 52 stacked with a second semiconductor chip 54. The first semiconductor chip includes an array of non-volatile memory cells. The memory array 58, as shown schematically in FIG. 4, is read from by applying a first voltage to the array and is written to by applying a second voltage to the array. This second voltage can be generated on the high voltage chip 54.

The schematic of FIG. 4 illustrates a portion of an array of floating gate memory cells 58. These memory cells are arranged in a matrix of rows and columns, each column of cells being electrically coupled to a bitline BL and each row of memory cells being coupled by a wordline WL. Each of the wordlines WL is coupled to a programming circuit 60 that can provide a high voltage to the array for programming. Other circuitry necessary to operate the array, such as addressing circuits and read circuits are not shown for the sake of simplicity. It is also possible to use other types of memory cells, such as charge trapping memory cells, for example.

The high voltage circuitry is provided in the chip 54. As discussed by Brown and Brewer, Nonvolatile Semiconductor Memory Technology: A Comprehensive Guide to Understanding and Using NVSM Devices, IEEE Press, 1998, p. 282, the voltage required to operate flash memories can range from 12 V for stacked gate flash to 25 V for poly-to-poly tunnel erase. In other technologies, other operating voltages can be used. In order to handle these voltages, various isolation processes are utilized to provide sufficiently high-field turn-on voltage, as well as a sufficiently high junction break-down voltage. For example, a thicker field oxide compared to logic technology of a comparable generation can be used. In another example, deep trench isolation can be used. In addition to isolation technology, the transistor technology must also handle the high voltage. Provision of the high voltage and low voltage portions of the circuit on different chips helps to simplify the processing of these different technologies and can improve the yield due to reduced process steps for each chip.

As shown in FIG. 3, the semiconductor chips 52 and 54 are stacked such that the higher voltage is provided to the array circuitry via at least one through-via 56. In the illustrated example, the non-volatile memory chip 52 is mounted face down on a substrate 62. That is, the active circuitry, such as the array 58, of FIG. 4, are formed at the surface of the chip 52 closest to the substrate 62. This circuitry receives the higher voltage from the through-via 56, which extends from the active surface to the backside surface of the chip 52. In one example, the higher voltage is at least twice as large as the lower voltage.

In one example, the high voltage circuit 54 can receive the lower voltage from through-via 57 and generate the high voltage from the low voltage. In another example, the high voltage circuit includes further connects to receive the low voltage supply, e.g., an external connection to the substrate 62 or to other circuitry.

In the example of FIG. 3, only the first chip 52 includes a through-via. The high voltage chip 54 is the top chip in the stack and, therefore, does not require a through-via. Other configurations are also possible.

For example, FIG. 5 illustrates a configuration where a high voltage chip 54 is sandwiched between memory array chips 52a and 52b. In this case, the high voltage chip 54 includes through-vias 56 and 57, which provide the supply voltages as described above. To illustrate one of the many options, wire bonds 64 are shown to electrically couple the non-volatile memory chips 52a and 52b to the substrate 62.

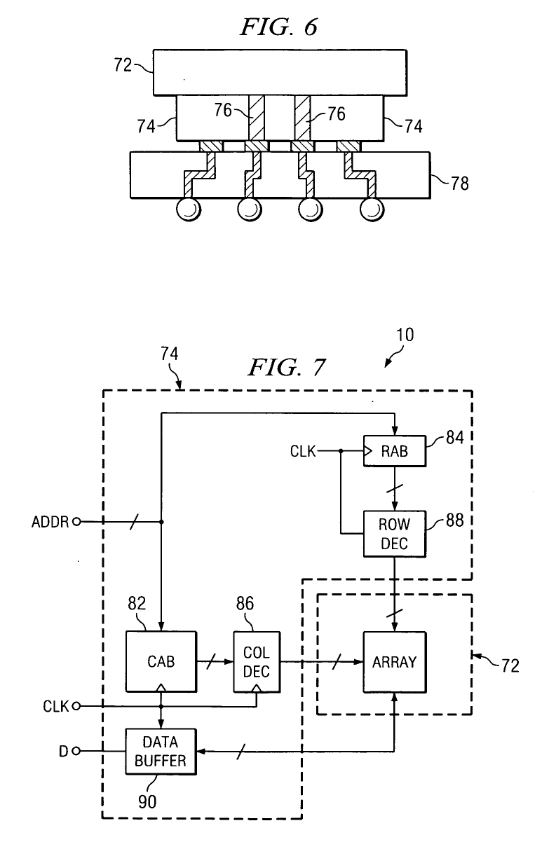

FIGS. 6-8 illustrate another example that can utilize the concepts of the present invention. In this embodiment, the first semiconductor chip 72 includes an array of dynamic random access memory (DRAM) cells. The second semiconductor chip 74 includes peripheral circuitry for accessing the array 72. One of the issues with conventional DRAM processing is the use of a buried channel PMOS transistor, which lowers the production costs but with a sacrifice in performance. By separating out the logic portions of the DRAM device, this issue can be resolved.

In this embodiment, the NMOS technology used to fabricate the array can be put on a separate level as the CMOS technology used for the periphery or logic portions of the array. As a result of this separation, the issue of process compatibility is resolved, which can result in a low cost, high performance DRAM cell where both the NMOS and the PMOS devices are optimized.

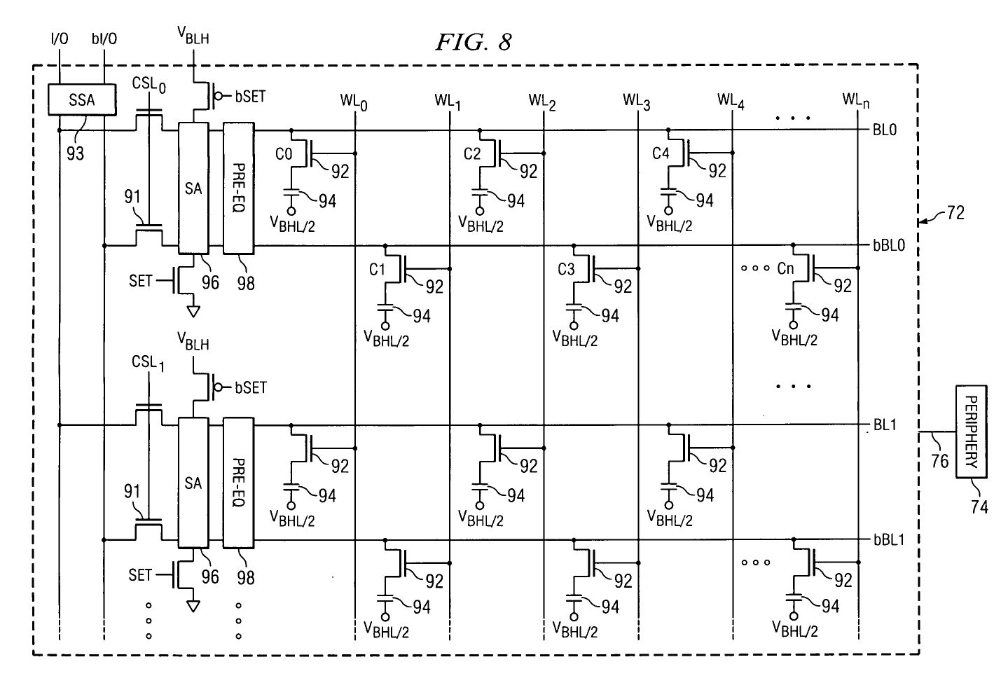

For example, in conventional memory devices the access transistors (92 in FIG. 8), and the spacing between adjacent access transistors, must be very small. Each access transistor includes a gate and a spacer arranged along a sidewall of the gate. Two adjacent access transistors sharing a bitline contact that is formed adjacent the spacers of the two adjacent access transistors. The bitline contact being self-aligned with the spacers.

In one example, the peripheral circuitry, including both n-channel and p-channel transistors, is provided in the chip 74. This chip includes through-vias 76 through which the memory array 72 can be accessed. Since the external input/output connects are provided through the peripheral circuitry, this chip 74 is mounted on the substrate 78. This configuration is not necessary.

One advantage of this configuration is that the transistors can be optimized. For example, in a conventional DRAM, it is common to dope the gates of both the n-channel and the p-channel periphery transistors with n-type dopants. This creates buried p-channel transistors, which must be counterdoped with a p-type implant in order to operate properly. While this reduces process costs, it increases the susceptibility of the p-channel transistor to punchthrough and can result in fairly large p-channel transistors.

In embodiments of the present invention, on the other hand, each n-channel transistor of the peripheral circuitry includes an n-doped gate and each p-channel transistor of the peripheral circuitry includes a p-doped gate. This can be easily achieved using standard logic processing and without concern for the array, which is being processed separately. Likewise, the array can be fabricated using only NMOS transistors, that is, so that each and every one of the transistors is an NMOS transistor (i.e., without any PMOS transistors).

In another embodiment, the NMOS portions of the DRAM (including the logic and array areas) are laid out so that deep silicon contacts from a PMOS chip can connect to the appropriate points. The NMOS and PMOS chips are processed separately and then bonded together to form a 3D stack with high performance and low cost. Additional levels can be added as per layout guidelines and density requirements of the product.

FIGS. 7 and 8 provide further detail as to the circuits in chips 72 and 74. FIG. 7 illustrates a functional block diagram of a DRAM device. To access a particular cell in the array 72, an address selection signal ADDR is transmitted to a Column Address Buffer (CAB) 82 and Row Address Buffer (RAB) 84. In a typical DRAM chip, the column address and row address share external pins so that the row address is received at a first time and the column address is received at a second time. The ADDR signals may be transmitted by an external device, such as a memory controller (not shown), for example.

The column address buffer 82 and row address buffer 84 are adapted to buffer the address signal. The outputs of the column address buffer 82 and row address buffer 84 are coupled to a column decoder 86 and row decoder 88, respectively. The column and row decoders 86 and 88 are adapted to decode the signals received from the column address buffer 82 and row address buffer 84, respectively, to provide the signal input to the array 72 such that the selected row and column can be selected.

In FIG. 7, the decoders 86 and 88 are shown as single blocks. It should be understood, however, that the decoders may carry out several levels of pre-decoding and decoding. Some or all (or none) of these levels may be clocked.

Data D that is addressed in array 72 will be written into or read from memory via data buffer (DB) 90. Once again, this portion of FIG. 1 is simplified. The data buffer 90 and associated line are provided to represent the read and write path, which may include a large number of lines and other components (e.g., secondary sense amplifiers).

FIG. 7 also shows a clock input CLK to illustrate that the memory device could be synchronous. To further illustrate this point the clock signal CLK is provided to each of the blocks. It is understood that while the external clock could be provided to various elements in the array, a number of clocking signals, which may operate continuously or only when needed, may be derived from the clock.

FIG. 8 shows more detail of the memory array 72. As shown in FIG. 8, the memory array 72 includes a plurality of memory cells arranged in a matrix-type architecture or array. Each cell C₀, C₁, C₂ . . . Cₙ includes an access transistor 92, typically an n-channel metal oxide semiconductor field effect transistor (MOSFET), coupled in series with a capacitor 94, e.g., a trench capacitor or a stack capacitor. The gate of each access transistor 92 is coupled to a wordline WL₀, and one source/drain region of the transistor 92 is coupled to a bitline BL0, as shown. A second source/drain region of the transistor 92 is coupled to one end of the storage capacitor 94. The other end of the storage capacitor 94 is coupled to a reference voltage, such as V_{BHL}/2, for example.

The bitlines are organized as bitline pairs, e.g., BL0 and bBL0. Each bitline pair BL0/bBL0 is coupled to a sense amplifier 96, which is configured to amplify the voltage difference between the two bitlines in a pair. Mid-level sensing is accomplished using latch-type sense amplifiers with a bitline high (V_{BLH}) level of 1.5 V. Equalization and pre-charge circuitry 98 is also coupled between each bitline in a pair to provide the proper initial voltages on the bitlines.

In operation, the bitlines are pre-charged to an initial value, typically one half of the value of a physical one written into a cell. In the preferred embodiment, this voltage level is referred to as V_{BLH} (bitline high) and is about 1.5 V. Preferably, V_{BLH} is generated on-chip. The equalization circuitry is provided to ensure that each bitline in a pair is pre-charged to the same level, e.g., V_{BLH}/2 or about 0.75 V. The pre-charge and equalization circuitry is enabled by a signal EQL.

To read a data bit from the array, a high voltage (e.g., V_{PP}) is placed on a selected one of the wordlines WL. This signal will be generated by the row decoder 84 (FIG. 7). The supply voltage V_{PP} can be derived from the external supply voltage or can be generated in chip 74, for example.

The high voltage on the wordline will cause the pass transistor of each memory cell coupled to that wordline to be conductive. Accordingly, charge will travel either to the bitline from the memory cell (in the case of a physical one, e.g., V_{BHL}) or from the bitline to the memory cell (in the case of a physical zero, e.g., 0V). The sense amplifier 96, when activated by signal SET, will sense the physical one or zero and generate a differential voltage that corresponds with the signal read from the cell.

A pair of pass transistors 91 is provided between each column and the local input/output lines I/O and bI/O. Since the sense amplifier 96 associated with each column (only BL₀/bBL₀ and BL₁/bBL₁ are shown) will generate a bit that corresponds to cells associated with the selected row (as determined by the selected wordline), a column select signal CSLₙ is provided to the pass transistors 91 to select one of the columns, which is coupled to the local I/O. (Of course, some architectures will include multiple I/O's in which case a single select signal CSLₙ is coupled to the pass transistors of more than one column.)

A secondary sense amplifier (SSA) 93 is coupled to each I/O line to amplify the voltage level. The SSA 93 is timed off of the logic that enabled the CSL. In the preferred embodiment, this circuitry contains not only a sense amplifier for reading but also write buffers for driving the I/O lines. Basically the “SSA” can be in one of three states: precharged (if no read or write), reading, or writing.

When a read command is issued, the CSLs get activated, and the sense amplifiers (basically clocked latches) are connected to the I/O lines. The clocking of the latches is synchronized with the CSL activation. When a write command is issued, the CSLs are again activated, but the sense amplifier is disconnected from the I/O lines and the write drivers are connected instead. As in the case of a read, the clocking of the drivers is synchronized with the CSL activation.

A write operation will be performed in a similar fashion as a read. First, a wordline must have been previously activated, e.g., a bank is active. Subsequently, data is placed on the I/O lines and the CSLs are activated. This overwrites the primary sense amplifier, causing the BL and bBL to change (only in the case of a different data state) and the data is transferred to the memory cell.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for forming a semiconductor component, the method comprising:
forming a first semiconductor chip using a first process technology, the first semiconductor chip having an upper surface with active circuitry and a lower surface opposed to the upper surface;
forming a plurality of through-vias in the first semiconductor chip;
thinning the first semiconductor chip such that, at least after the thinning, each through-via extends from the upper surface to the lower surface;
forming a second semiconductor chip using a second process technology, the second process technology being different than the first process technology, the second semiconductor chip having a plurality of contacts at a surface; and
mounting the first semiconductor chip adjacent the semiconductor chip such that ones of the through-vias are electrically coupled to associated ones of the contacts.

2. The method of claim 1, wherein forming a first semiconductor chip using a first process technology comprises forming a semiconductor chip with high-voltage devices and wherein forming a second semiconductor chip using a second process technology comprises forming a semiconductor chip with low-voltage devices.

3. The method of claim 2, wherein the second memory chip comprises an array of non-volatile memory cells and wherein the first semiconductor chip comprises circuitry to process the memory cells in the array of non-volatile memory cells.

4. The method of claim 3, wherein the non-volatile memory cells comprise floating gate flash memory cells.

5. The method of claim 3, wherein the non-volatile memory cells comprise charge-trapping memory cells.

6. The method of claim 1, wherein forming a first semiconductor chip using a first process technology comprises forming a semiconductor chip with analog circuits and wherein forming a second semiconductor chip using a second process technology comprises forming a semiconductor chip with digital circuits.

7. The method of claim 1, wherein forming a first semiconductor chip using a first process technology comprises forming a semiconductor chip using a bipolar process and wherein forming a second semiconductor chip using a second process technology comprises forming a semiconductor chip using a CMOS process.

8. The method of claim 1, wherein forming a second semiconductor chip using a second process technology comprises forming an array of memory cells and wherein forming a first semiconductor chip using a first process technology comprises forming peripheral circuitry coupled to the array of memory cells through the through-vias, the peripheral circuitry operable to access information to and from addressed areas of the array.

9. The method of claim 8, wherein the array of memory cells comprises an array of dynamic random access memory cells.

10. The method of claim 9, wherein the second semiconductor chip includes a plurality of transistors, each and every one of the transistors comprising an NMOS transistor.

11. The method of claim 1, wherein the plurality of contacts of a second semiconductor device comprise through-vias.

12. The method of claim 11, further comprising thinning the second semiconductor chip such that each through-via extends from the surface to an opposed surface.

13. A memory device comprising:
a first semiconductor chip including an array of non-volatile memory cells, the memory array being read from by applying a first voltage to the array and being written to by applying a second voltage to the array, the second voltage being higher than the first voltage; and
a second semiconductor chip having an external input node for receiving the first voltage, the second semiconductor chip having circuitry operable to generate the second voltage from the first voltage;
wherein the first and second semiconductors are stacked such that the second voltage is provided to the first semiconductor chip from the second semiconductor chip via at least one through-via, the at least one through-via located in an internal portion of one of the first semiconductor chip or the chip semiconductor chip and extending from an upper surface to an opposed lower surface of the one semiconductor chip.

14. The device of claim 13, wherein the array of non-volatile memory cells comprises an array of flash memory cells.

15. The device of claim 14, wherein the array of non-volatile memory cells comprises an array of floating gate memory cells.

16. The device of claim 13, wherein the first semiconductor chip includes a plurality of transistors having a first minimum dimension and the second semiconductor chip includes a plurality of transistors having a second minimum dimension, the second minimum dimension being larger than the first minimum dimension.

17. The device of claim 16, wherein the second minimum dimension is more than twice as large as the first minimum dimension.

18. The device of claim 13, wherein the first semiconductor chip includes a plurality of transistors, each having a gate dielectric of a first thickness and wherein the second semiconductor chip includes a plurality of transistors, each having a gate dielectric of a second thickness, the second thickness being larger than the first thickness.

19. The device of claim 13, wherein the second voltage is at least twice as large as the first voltage.

20. The device of claim 18, wherein the first voltage is 1.5 V or less and the second voltage is 3.0 V or more.

21. A memory device comprising:
a first semiconductor chip including an array of dynamic random access memory cells, each memory cell including an access transistor coupled to a storage capacitor, the first semiconductor chip having no p-channel transistors disposed thereon; and
a second semiconductor chip including peripheral circuitry for accessing the array of memory cells, the peripheral circuitry including both n-channel and p-channel transistors interconnected to form the circuitry;
wherein the first and second semiconductors are stacked such that peripheral circuitry accesses the array of dynamic random access memory cells via a plurality of through-vias, the through-vias being located in an internal portion of one of the first semiconductor chip or the second semiconductor chip and extending from an upper surface to an opposed lower surface of the one semiconductor chip.

22. The device of claim 21, wherein each memory cell comprises an access transistor coupled to a trench capacitor, the trench capacitor extending into semiconductor material of the first semiconductor chip.

23. The device of claim 21, wherein each n-channel transistor of the peripheral circuitry comprises an n-doped gate and each p-channel transistor of the peripheral circuitry comprises a p-doped gate.

24. The device of claim 21, wherein the peripheral circuitry includes address buffers and decoders coupled between external inputs and the through-vias.

25. The device of claim 24, wherein the through-vias are located in the second semiconductor chip, the second semiconductor chip further including contacts for receiving signals from an external source.

26. The device of claim 21, wherein each access transistor comprises a gate and a spacer arranged along a sidewall of the gate, two adjacent access transistors sharing a bitline contact that is formed adjacent the spacers of the two adjacent access transistors, the bitline contact being self-aligned with the spacers.
